(19) United States
(12) Patent Application Publication
(10) Pub. No.: US 2016/0081234 A1
(43) Pub. Date: Mar. 17, 2016

(54) PACKAGE STRUCTURE

(71) Applicant: Siliconware Precision Industries Co., Ltd., Taichung (TW)

(72) Inventors: Chih-Hsien Chiu, Taichung (TW); Hsin-Lung Chung, Taichung (TW); Chia-Yang Chen, Taichung (TW); Chao-Ya Yang, Taichung (TW); Yude Chu, Taichung (TW); Chih-Ming Cheng, Taichung (TW)

(21) Appl. No.: 14/607,743

(22) Filed: Jan. 28, 2015

(30) Foreign Application Priority Data
Sep. 12, 2014 (TW) 103131512

(51) Int. Cl. H05K 9/00

(52) U.S. Cl. CPC H05K 9/0022

(57) ABSTRACT

A package structure is provided, including an electronic element with a low frequency, a shielding member connected to the electrosnic element, and an encapsulant covering the electronic element and the shielding member, such that the electronic element is shielded from erroneous signals.

### BACKGROUND OF THE INVENTION

1. Field of the Invention

The present invention relates to package structures, and, more particularly, to a package structure having an electromagnetic shielding function.

2. Description of Related Art

With the rapid growth in electronic industry, there is an increasing need in developing electronic products with multi-functionality and high performance. As wireless technology has been widely applied in all types of electronic products which are capable of transmitting or receiving wireless signals, the electronic products are configured with a shielding function in order to prevent electromagnetic interference (EMI).

Electronic products up to date have been developed towards miniaturization and high operational speed. In particular, these electronic products have been widely incorporated into communication products, such as cell phones, laptops, etc. These types of electronic products require the use of radio frequency chip of high frequency. These radio frequency chips may be disposed in an integrated circuit, a digital signal processor, (DSP) or a base band chip, which are likely to be interfered with respect to each other, and, as a result, require electromagnetic shielding.

As shown in FIG. 1, an conventional radio frequency module 1 comprises a carrier 10, a plurality of electronic components 11 electrically connected to the carrier 10, an encapsulant 13 made by epoxy resin and encapsulating the electronic components 11, and a metal thin film 12 formed and covering the encapsulant 13. With the metal thin film 12, the electronic components 11 of the radio frequency module 1 is protected from the interference of EMI.

However, in the radio frequency module 1 the metal thin film 12 is formed on an external side of the encapsulant 13. In other words, the encapsulant 13 is formed between the metal thin film 12 and the interference source (i.e., electronic component 11). When the electronic component 11 is a radio frequency chip, the metal thin film 12 covers top and side surfaces of the encapsulant 13, resulting in a poor shielding effect, causing erroneous signals of the electronic component 11 of low frequency.

Accordingly, there is an urgent need to solve the above-mentioned drawbacks of the prior art.

### SUMMARY OF THE INVENTION

In view of the above-mentioned drawbacks of the prior art, the present invention discloses a package structure, comprising: at least one electronic component with a low frequency; at least one shielding member coupled onto the at least one electronic component; and an encapsulant encapsulating the electronic component and the shielding member.

In an embodiment, the electronic component is a package substrate, an active component, a passive component or a conductive circuit.

In an embodiment, the low frequency refers to a frequency lower than or equal to 3 MHz.

In an embodiment, the electronic component is a low frequency electronic component.

In an embodiment, the shielding member is coupled onto at least one of the electronic components via a bonding layer, and the bonding layer is formed between the shielding member and the electronic component.

In an embodiment, the shielding member is made of a soft ferrite material.

In an embodiment, the heat resistance temperature of the shielding member is 300□.

In an embodiment, another electronic component is disposed on the shielding member.

In an embodiment, the width of the shielding member is less than, greater than or equal to the width of the electronic component.

In an embodiment, the shielding member completely or partially covers the electronic components.

In an embodiment, a portion of the shielding member is exposed from the encapsulant.

In an embodiment, the encapsulant is not formed between the shielding member and the electronic components

In an embodiment, the package structure further comprises a carrier that carries the electronic components and is electrically connected with the electronic components.

Accordingly, in the package structure according to the present invention, the direct coupling of the shielding member to the low frequency electronic components, in replacement of the disposing of the shielding member on the external side of the encapsulant according to the prior art, can prevent the low frequency electronic component from generating erroneous signals.

### BRIEF DESCRIPTION OF THE DRAWINGS

FIG. 1 is a cross-sectional view showing a conventional radio frequency module;

FIG. 2 is a cross-sectional view showing a package structure in accordance with a first embodiment of the present invention; wherein FIGS. 2′ and 2″ are other embodiments of FIG. 2;

FIGS. 3A-3E are cross-sectional views showing package structures in accordance with different types of a second embodiment of the present invention;

FIG. 4 is a cross-sectional view of a package structure in accordance with a third embodiment of the present invention;

FIG. 5 is a cross-sectional view of a package structure in accordance with a fourth embodiment of the present invention;

FIG. 6 is a cross-sectional view of a package structure in accordance with a fifth embodiment of the present invention;

FIGS. 7 and 7′ are cross-sectional views of a package structure in accordance with a sixth embodiment of the present invention; and

FIG. 8 is a cross-sectional view of a package structure in accordance with an seventh embodiment of the present invention.

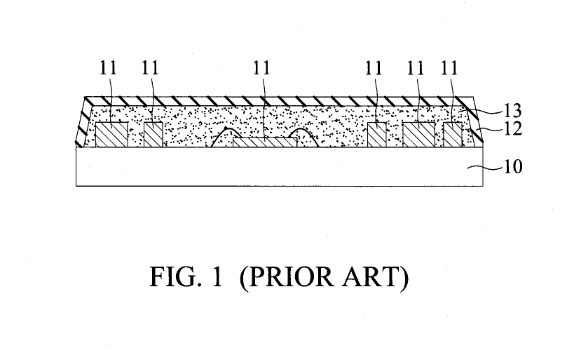

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “on”, “second”, “first”, and etc., are merely for illustrative purpose and should not be construed to limit the scope of the present invention.

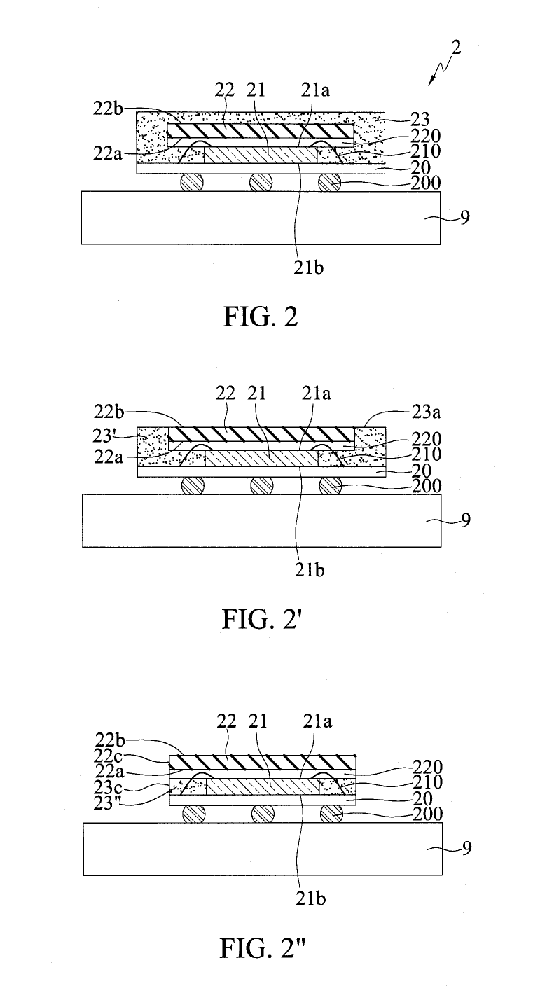

FIG. 2 is a cross-sectional view showing a package structure 2 in accordance with a first embodiment of the present invention. In an embodiment, the package structure 2 is a radio frequency module of a system in package (SiP).

The package structure 2 comprises an electronic component 21, a shielding member 22 coupled onto the electronic component 21, and an encapsulant 23 encapsulating the electronic component 21 and the shielding member 22.

The electronic component 21 can be an active component, or a passive component, such as a capacitor or an inductor. In an embodiment, the electronic component 21 is a low frequency active component.

The shielding member 22 has first and second surfaces 22a and 22b. The first surface 22a of the shielding member 22 is coupled to an upper surface 21a of the electronic component 21 via a bonding layer 220 such as an adhesive, and the bonding layer 220 is formed between the first surface 22a of the shielding member 22 and the electronic component 21. In an embodiment, the shielding member 22 is made of a soft ferrite material, and the heat resistance temperature of the shielding member can reach to 300□.

The encapsulant 23 is not formed between the first surface 22a of the shielding member 22 and the electronic component 21.

In an embodiment, the package structure 2 further comprises a carrier 20 carrying the electronic component 21, and the lower surface 21b of the electronic component 21 is coupled to the carrier 20.

In an embodiment, the carrier 20 is a circuit board or a ceramic board. A wiring layer (not shown) is formed on a surface of the carrier 20 and is electrically connected with the electronic component 21. In an embodiment, the electronic component 21 is electrically connected to the wiring layer via a plurality of bonding wires 210.

In an embodiment, the carrier 20 has an inner wiring layer (not shown), and is externally connected to another electronic device 9 (such as a printed circuit board) via conductive elements 200 such as solder balls.

The carrier 20 may be in a variety of types, and is not limited by what is shown in the drawings.

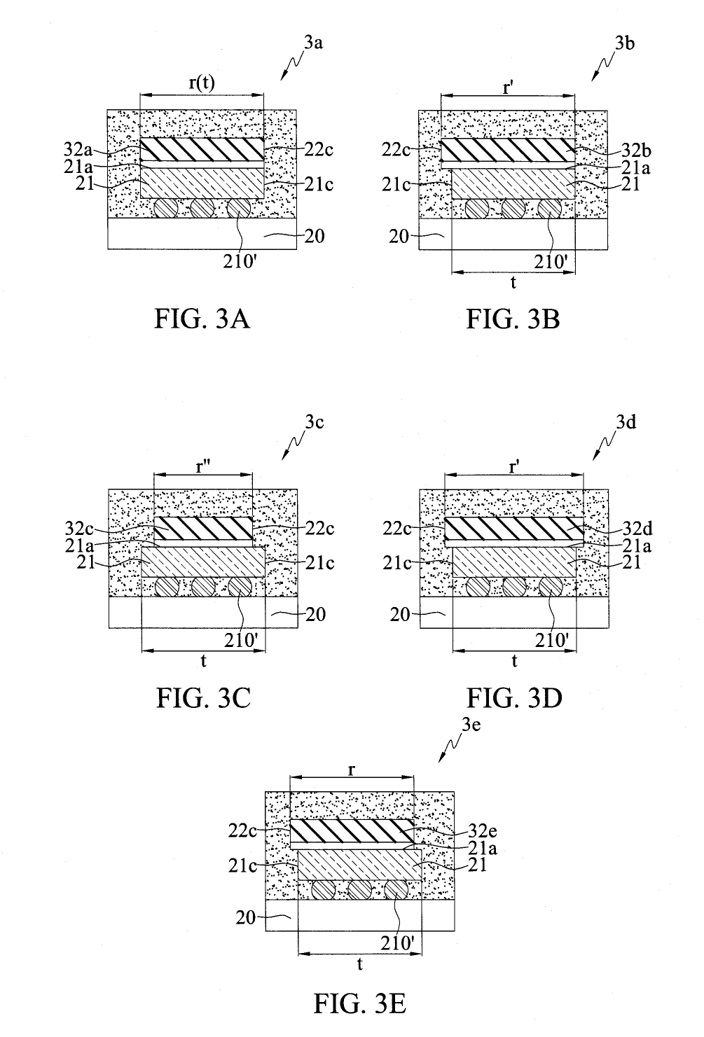

FIGS. 3A-3E are cross-sectional views showing the package structures 3a, 3b, 3c, 3d and 3e in accordance with a second embodiment of the present invention. The second embodiment differs from the first embodiment in the various types of the shielding members 32a, 32b, 32c, 32d and 32e.

As shown in FIGS. 3A and 3E, the width 4 of the shielding members 32a and 32e is equal to the width t of the electronic component 21.

As shown in FIGS. 3B and 3D, the width r′ of the shielding members 32b and 32d is greater than the width t of the electronic component 21.

As shown in FIG. 3C, the width 4′ of the shielding member 32b is lesser than the width t of the electronic component 21.

In an embodiment, the electronic component 21 is electrically connected to the wiring layer (not shown) of the carrier 20 via a plurality of solder balls 210′ in a flip-chip manner.

In an embodiment, the shielding members 32a and 32b, 32d completely cover the upper surface 21a of the electronic component 21. As shown in FIG. 3A, the side 22c of the shielding member 32a is flush with the side 21c of the electronic component 21. As shown in FIG. 3B, the side 22c of the shielding member 32b protrudes from the side 21c of the electronic component 21. As shown in FIG. 3D, the left and right sides 22c (and/or the front and back sides) of the shielding member 32d protrude from the side 21c of the electronic component 21.

As shown in FIG. 3C, since the width r′ of the shielding member 32b is less than the width t of the electronic component 21, the shielding member 32c partially covers the upper surface 21a of the electronic component 21.

When the widths r and r′ of the shielding members 32a, 32e, 32b and 32d are equal to the width t of the electronic component 21, the shielding members 32a, 32e, 32b and 32d can be placed slightly off a centre of the upper surface 21a of the electronic component 21, such that the upper surface 21a of the electronic component 21 is exposed. As shown in FIG. 3E, the shielding member 32e partially covers the upper surface 21a of the electronic component 21.

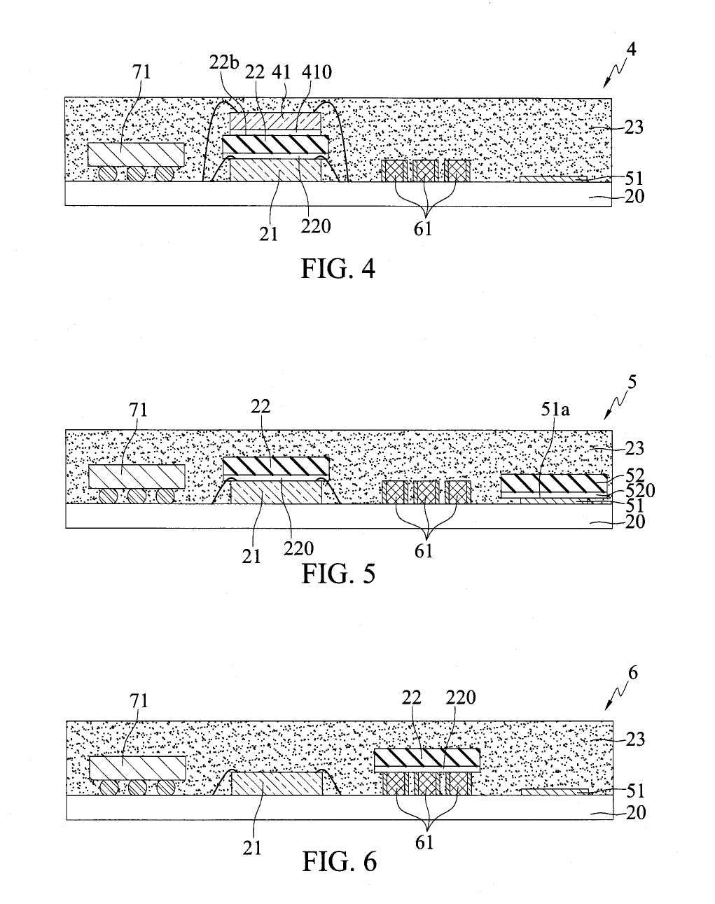

FIG. 4 is a cross-sectional view of a package structure 4 in accordance with a third embodiment of the present invention. The third embodiment differs from the first embodiment in that in the third embodiment additional electronic components are included.

As shown in FIG. 4, the package structure 4 further comprises another electronic component 41 disposed on the second surface 22b of the shielding member 22.

The electronic component 41 is coupled onto the second surface 22b of the shielding member 22 via a bonding layer 410, and the encapsulant 23 also encapsulates the electronic component 41 formed on the second surface 22b of the shielding member 22.

In an embodiment, the electronic component 41 is an active or a passive component, and is not a low frequency component.

The carrier 20 is used to carry a plurality of electronic components 21, 41, 51, 61 and 71, and the shielding member 22 is coupled to one electronic component 21 only. In an embodiment, the electronic component 51 is a conductive circuit, and the other electronic components 61 are passive components. The electronic component 71 is another package unit, and the electronic components 51, 61 and 71 are not low frequency components and do not need shielding member mounted thereon.

The encapsulant 23 encapsulates the electronic components 21, 51, 61 and 71.

FIG. 5 is a cross-sectional view of a package structure 5 in accordance with a fourth embodiment of the present invention. The fourth embodiment differs from the third embodiment in that in the fourth embodiment a plurality of shielding members which are connected to the electronic components, respectively, are further included.

As shown in FIG. 5, the electronic component 51 is a low frequency conductive circuit, and the other electronic components 61 and 71 are not low frequency components. The shielding members 22 and 52 are coupled to the low frequency electronic components 21 and 51, respectively, via the bonding layers 220 and 520.

In an embodiment, the shielding member 52 covers a portion or the entire upper surface 51a of the electronic component 51, and partially or entirely cover the low frequency conductive circuit.

Moreover, the encapsulant 23 encapsulates the electronic components 21, 51, 61 and 71.

FIG. 6 is a cross-sectional view showing a package structure 6 in accordance with a fifth embodiment of the present invention. The fifth embodiment differs from the third embodiment in that in the fifth embodiment a single shielding member is coupled to a plurality of electronic components.

As shown in FIG. 6, the carrier 20 carries a plurality of electronic components 21, 51, 61 and 71, and the electronic component 61 is a low frequency passive component, while the other electronic components 21, 51 and 71 are not low frequency components. Therefore, the shielding member 22 is coupled to the low frequency electronic component 61 only.

Moreover, the encapsulant 23 encapsulates the electronic components 21, 51, 61 and 71.

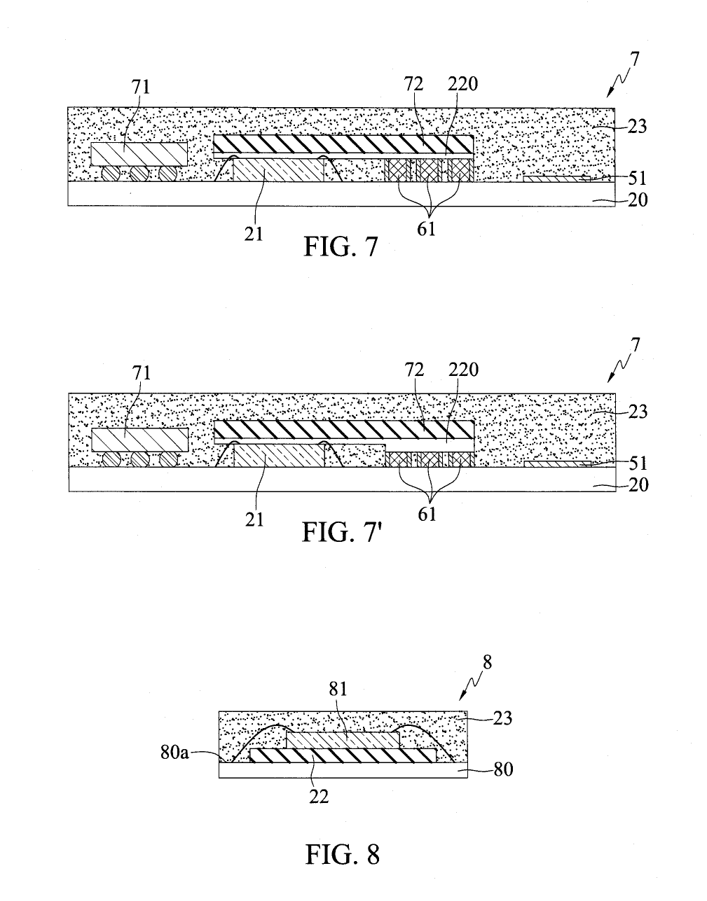

FIG. 7 is a cross-sectional view showing a package structure 7 in accordance with a sixth embodiment of the present invention. The sixth embodiment differs from the third embodiment in that in the sixth embodiment a single shielding member is coupled to a plurality of different electronic components.

As shown in FIG. 7, the carrier 20 carries a plurality of electronic components 21, 51, 61 and 71, the electronic components 21 and 61 are low frequency components, and the single shielding member 72 is coupled to the electronic components 21 and 61. The other electronic components 51 and 71 are not low frequency components, and no shielding member is formed on the electronic components 51 and 71.

In an embodiment, the electronic components 21 and 61 have different heights. In another embodiment, the electronic components 21 and 61′ may also have different heights, as shown in FIG. 7′.

Furthermore, the encapsulant 23 encapsulates the electronic components 21, 51, 61 and 71.

In an embodiment, the shielding member can be installed on the electronic component 71 according to practical needs.

In an embodiment, a portion of the shielding member is exposed from the encapsulant. For example, the second surface 22b of the shielding member 22 is flush with the surface 23a of the encapsulant 23′, as shown in FIG. 2′; or the side 22c of the shielding member 22 is flush with the side 23c of the encapsulant 23″, as shown in FIG. 2″.

FIG. 8 is a cross-sectional view showing a package structure 8 in accordance with a seventh embodiment of the present invention. The seventh embodiment differs from the third embodiment in the types of low frequency electronic components.

As shown in FIG. 8, the low frequency electronic component 80 is a packaging substrate, and a shielding member 22 is coupled onto the electronic component 80. The shielding member 22 carries a non-low frequency electronic component 81.

In an embodiment, the non-low frequency electronic component 81 is an active component, or a passive component, such as a resistor, a capacitor and an inductor, and the encapsulant 23 encapsulates the upper surface 80a of the low frequency electronic component 80 and the non-low frequency electronic component 81.

In addition, the shielding member 22 covers the upper surface 80a of the electronic component 80, without having specific limitations.

In an embodiment, the low frequency refers to a frequency less than 3 MHz.

In summary, in a package structure according to the present invention, the direct coupling of the shielding members 22, 52 and 72 onto the low frequency electronic components 21, 51 and 61 allows the shielding members 22, 52 and 72 to be installed inside the encapsulants 23 and 23′, rather than installed on the outside of the encapsulants 23 and 23′. Therefore, the distance between the shielding member and the interference source is reduced, and an optimal shielding effect for low frequency interference is obtained. Hence, the low frequency electronic components 21, 51 and 61 are prevented from generating erroneous signals.

Further, since the shielding member 22 is in direct contact with the low frequency electronic components 21, 51 and 61, there is no need to shield the side 21c of the low frequency electronic components 21, 51 and 61. Therefore, the low frequency electronic components 21, 51 and 61 can be well shielded.

Moreover, the shielding members 22, 52 and 72 are installed inside of the encapsulants 23 and 23′, and the encapsulants 23 and 23′ encapsulate the shielding members 22, 52 and 72. Therefore, the overall height of the package structures 2, 3a-3e, 4, 5, 6 and 7 can be reduced.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A package structure, comprising:
at least one electronic component with a low frequency;
at least one shielding member coupled onto the at least one electronic component; and
an encapsulant encapsulating the electronic component and the shielding member.

2. The package structure of claim 1, wherein the electronic component is a package substrate, an active component, a passive component or a conductive circuit.

3. The package structure of claim 1, wherein the low frequency is a frequency of less than 3 MHz.

4. The package structure of claim 1, wherein the shielding member is coupled onto the at least one electronic component by a bonding layer, and the bonding layer is formed between the shielding member and the electronic component.

5. The package structure of claim 1, wherein the shielding member is made of a soft ferrite material.

6. The package structure of claim 1, wherein the shielding member has heat resistance temperature equal to 300□.

7. The package structure of claim 1, further comprising another electronic component formed on the shielding member.

8. The package structure of claim 1, wherein the shielding member has a width less than, greater than or equal to a width of the electronic component.

9. The package structure of claim 1, wherein the shielding member completely or partially covers the electronic component.

10. The package structure of claim 1, wherein the shielding member has a portion exposed from the encapsulant.

11. The package structure of claim 1, wherein the encapsulant is not formed between the shielding member and the electronic component.

12. The package structure of claim 1, further comprising a carrier that carries and is electrically connected with the electronic component.
